(19) United States
(12) Patent Application Publication
(10) Pub. No.: US 2024/0059965 A1
(43) Pub. Date: Feb. 22, 2024

(54) LIGHTING DEVICE

(71) Applicant: Schott AG, Mainz (DE)

(72) Inventors: Albrecht Seidl, Mainz (DE); Ulrike Stöhr, Mainz (DE); Sylvia Biedenbender, Mainz (DE)

(73) Assignee: Schott AG, Mainz (DE)

(21) Appl. No.: 18/450,823

(22) Filed: Aug. 16, 2023

(30) Foreign Application Priority Data
Aug. 16, 2022 (DE) 10 2022 120 647.5

(51) Int. Cl. F21V 9/30; C09K 11/77; C09K 11/02

(52) U.S. Cl. CPC F21V 9/30; C09K 11/7774; C09K 11/02

(57) ABSTRACT

A lighting device includes: a light source configured for emitting a primary light; a light conversion unit formed by or including: a light conversion element including a front side and a rear side, wherein the light conversion element is configured for being illuminated by the primary light on the front side and for emitting a secondary light with an altered wavelength compared to the primary light on the front side, wherein the light conversion element includes a first phase including a light-converting ceramic material and a second phase including a further ceramic material, the second phase having a higher thermal conductivity than the first phase, and wherein the light conversion element includes a plurality of pores.

### CROSS REFERENCE TO RELATED APPLICATIONS

This claims priority to German patent application no. 10 2022 120 647.5, filed Aug. 16, 2022, which is incorporated herein by reference.

### BACKGROUND OF THE INVENTION

### 1. Field of the Invention

The present invention relates to a lighting device, and, more particularly, to a lighting device with a light conversion element.

### 2. Description of the Related Art

Light conversion elements, especially ceramic converters, generally include a particular material as phosphor, for example Ce-doped yttrium aluminium garnet (YAG) or Ce-doped lutetium aluminium garnet (LuAG). The specific phosphor especially determines the absorption spectrum and emission spectrum, which in turn affect the thermal conductivity of the light conversion element.

The thermal conductivity of the converter material has an influence on how high the optical power of exciting light or, more specifically, the luminance of the exciting light must be before the quantum efficiency of the phosphor falls because of excessively high temperature thereof to such an extent that a further increase in the optical power does not lead to any further increase in emitted output or luminance, meaning that the irradiance limit has been reached.

The thermal conductivity of the widely used and described Ce-doped garnet ceramics (for room temperature), depending on the exact composition, is roughly in the range from 5 to 10 W/mK and hence is already relatively high compared to other oxides (many oxides or else glasses have a thermal conductivity in the range of only 1 to 2 W/mK).

However, there are some oxides that have much higher thermal conductivity compared to the garnets. These include, for example, Al₂O₃ (especially corundum) at about 30 W/mK, MgO (magnesia) at about 40 W/mK, or BeO at about 300 W/mK. It should be noted that these literature values apply to monocrystalline materials, whereas the values in a ceramic microstructure can be much lower.

If a material having higher thermal conductivity than the Ce-doped garnets is mixed therewith to form a mixed ceramic, this mixed ceramic, under particular conditions, may enable a much higher irradiance or a much higher light output than a monophasic ceramic of the same kind with the same dimensions under the same conditions.

The use of mixed ceramics in converter elements is generally known from the literature and patent applications. Particular converter materials with particular proportions by volume for the converter ceramic or grain sizes, grain shapes, lengths of grain boundaries and the like are sometimes cited by way of description.

However, existing documents are typically directed to transmissive designs, for example for applications in the field of LED lighting.

By contrast, what is needed in the art is to utilize the advantages of mixed ceramics for efficient lighting devices with diffuse reflective design.

### SUMMARY OF THE INVENTION

The present invention relates to a lighting device having a primary light source and a light conversion element which is illuminated by the primary light and emits secondary light with an altered wavelength compared to the primary light.

To meet this need, the present invention discloses a lighting device including a light source for emission of primary light, especially in the form of a laser or light-emitting diode, optionally of a laser, and a light conversion unit.

The light conversion unit is formed by or includes a light conversion element having a front side and a rear side, wherein the light conversion element is set up to be illuminated by the primary light on its front side and to emit secondary light with an altered wavelength compared to the primary light on its front side.

The light conversion unit optionally also includes a substrate which is connected directly or indirectly to the rear side of the light conversion element and is optionally in the form of a heatsink.

The substrate optionally consists wholly or predominantly of a material having a thermal conductivity greater than 30 W/mK, optionally greater than 100 W/mK, optionally greater than 150 W/mK, optionally greater than 350 W/mK, and/or includes at least one ceramic and/or at least one metal and/or at least one ceramic-metal composite. Optionally, the substrate includes at least one metal, optionally selected from Cu, Al, Fe or Ni, especially Cu, for example Ni—P— and/or Au-coated Cu.

Likewise optionally, the light conversion unit further includes a binder which is present between the light conversion element and the substrate and optionally takes the form of an organic adhesive, glass, ceramic adhesive, inorganic adhesive, sintered sinter paste and/or metallic solder alloy, optionally of a metallic solder alloy or sintered sinter paste, optionally of a metallic solder alloy.

The light conversion element includes a first phase including a light-converting ceramic material and a second phase including a further ceramic material, where the second phase has a higher thermal conductivity than the first phase.

In addition, the light conversion element includes a multitude of pores. The pores especially serve to scatter light.

The degree of optical scatter (the coefficient of scatter) influences (together with the coefficient of absorption), in particular, the size of the proportion of converted backscattered, especially blue, exciting radiation, and also the extent to which the exciting radiation diffuses within the converter up to complete absorption, and also the extent to which the converted light diffuses within the converter until it leaves the converter again as useful light. Important indices such as the efficacy of a component, or the emission light spot size, are influenced by the scatter. For reflective (incidence and emission on the same side) lighting devices, the aim is a sufficiently large coefficient of optical scatter.

The light conversion element including a multitude of pores advantageously enables elevated light scatter in the light conversion element. As a result, it is especially possible to efficiently use mixed ceramics in reflective mode, for example for SSL (solid state lighting). Especially in the case of a mixed ceramic with phases having a low variance of refractive index, scatter increased by pores is particularly advantageous. For example, the refractive index of Al₂O₃ at about 1.77 is only slightly smaller than the refractive index of YAG (about 1.83). The optical scatter effect owing to the mixed ceramic on its own is therefore small and is distinctly elevated by the pores.

In the case of known, especially transmissive, illuminations, porosity, by contrast, is generally deliberately suppressed. There are some mentions of methods such as hot pressing (HIP) or spark plasma sintering in order to achieve high-density ceramics. Lower light scatter compared to the reflective lighting device is sometimes already achieved to a sufficient degree in the case of transmissive geometries by further extrinsic components.

The light conversion unit optionally includes at least one highly reflective coating, where the highly reflective coating is optionally a metallic coating and/or a metal-containing coating and/or a dielectric coating,optionally an Ag or Ag-containing coating. It may be the case, for example, that the light conversion element has, on its rear side, a reflection layer, especially a metallic reflection layer, optionally including or composed of Ag, especially in such a way that the rear side of the light conversion element has been coated with the reflection layer, and wherein the reflection layer has optionally been applied on the rear side of the light conversion element by vapor deposition, sputtering (thin layer) or printing (thick layer).

In one embodiment, the light conversion element has a reflection layer which is a thin layer. The thin layer optionally includes or consists of Ag and/or has a layer thickness from 50 nm to 500 nm, optionally from 100 nm to 350 nm, optionally from 125 nm to 300 nm, optionally from 150 nm to 250 nm. In some embodiments, the light conversion element has a thin layer including or consisting of Ag and a further thin layer including or consisting of Au. The further thin layer is optionally applied by vapor deposition or sputtering. The thin layer including or consisting of Au optionally has a layer thickness from 50 nm to 500 nm, optionally from 100 nm to 350 nm, optionally from 125 nm to 300 nm, optionally from 150 nm to 250 nm. The thin layer including or consisting of Au may serve to protect the reflection layer including or consisting of Ag from oxidation reactions, which occur particularly at higher temperatures that can exist, for example, in the bonding of the light conversion element to the substrate, for example to a sinter paste.

In one embodiment, the light conversion element has a reflection layer which is an Ag-containing thick layer. The thick layer optionally has a layer thickness from 1 μm to 25 μm, optionally from 5 μm to 20 μm, optionally of from 10 μm to 15 μm.

The light conversion element may alternatively or additionally have been rendered reflective on its rear side with a dielectric layer system which is optimized particularly for maximum reflection.

The dielectric layer system may optionally be concluded on the outside by a metallic reflection layer. Accordingly, the layer sequence is converter element—dielectric layer system—metallic minor layer.

Alternatively, or additionally to a highly reflective coating on the rear side of the light conversion element, the light conversion element may be bonded on the rear side to a minor, optionally to an Ag mirror or to a silver-coated substrate, where the minor is optionally formed by the substrate or has been applied to the substrate.

It may be the case that the light conversion unit includes at least one optical separation layer which is optionally between the at least one highly reflective layer and the rear side of the light conversion element, where the at least one optical separation layer is optionally transparent and/or has a lower refractive index than the refractive index of the light conversion element, wherein the at least one optical separation layer optionally includes or consists of SiO₂.

The optical separation layer optionally has a thickness below 5 μm, optionally below 3 μm, optionally in the range from 0.5 to 1.5 μm, optionally in the range from 0.8 to 1.2 μm. The optical separation layer may serve to separate the reflection and any total reflection of the secondary light that reaches the rear side of the converter at the rear side of the converter from the reflection of the proportion of the secondary light that passes through the rear side of the converter at a highly reflective layer, especially at a metallic minor.

It may be the case that, between the at least one highly reflective layer, optionally a metallic coating or metal-containing coating, and the optical separation layer, there is a transparent adhesion promoter layer, optionally including or consisting of one or more oxides selected from the group consisting of SnO₂, TiO₂, Y₂O₃ and La₂O₃, optionally Y₂O₃. Optionally, the adhesion promoter layer has a thickness of 1 nm or more and/or less than 100 nm, optionally less than 75 nm, optionally of less than 50 nm, optionally of less than 35 nm, andoptionally of less than 20 nm.

The optionally included binder may be at least one organic adhesive, at least one glass, at least one ceramic adhesive, at least one inorganic adhesive, at least one sintered sinter paste and/or at least one metallic solder alloy.

The binder may especially take the form of a bonding layer.

In an optional embodiment, the bonding layer is formed from at least one adhesive. Suitable adhesives are organic adhesives that have properties suitable for the specific use and the specific construction of the respective converter, for example with regard to thermal stability, thermal conductivity, transparency and curing characteristics.

An optional embodiment includes filled and unfilled epoxy resins and silicones. Bonding layers based on adhesives typically have a layer thickness from 5 to 70 μm, optionally from 10 to 60 μm, optionally from 20 to 50 μm and optionally from 30 to 50 μm.

In a further optional embodiment, the bonding layer is a glass, optionally selected from a solder glass or a thin glass.

A solder glass especially includes specific glasses having a comparatively low softening temperature of not more than 750° C., optionally not more than 560° C. In principle, glass solders may be used in various forms, for example as powder, as paste in a liquid medium, or embedded in a matrix, which is applied to the converter substrate or the converter component. The applying can be effected by way of discharging a strand, by screen printing, by spraying, or in loose powder form. Subsequently, the individual components of the converter are assembled.

In an optional embodiment, a paste containing glass powder is used, for example a PbO-, a Bi2O3-, a ZnO-, an SO3-, a B2O3- or a silicate-based glass, optionally a silicate-based glass.

Thin glass in the context of the present application is thin glass having a maximum thickness of not more than 50 μm and a softening temperature of not more than 750° C., optionally not more than 560° C. Such glasses may be positioned between converter component and converter substrate and be pressed together at a sufficiently high temperature and sufficiently high pressure. Suitable thin glasses include borosilicate glasses, available, for example, as D263® from SCHOTT.

Bonding layers based on glass have, for example, a layer thickness of 15 to 70 μm, optionally of 20 to 60 μm, and optionally 30 to 50 μm.

In another embodiment, the light conversion element is bonded to the substrate via a ceramic adhesive.

Such ceramic adhesives are typically essentially free of organic constituents and have high thermal stability. An option is given to choosing a ceramic adhesive such that the coefficient of thermal expansion and the mechanical properties, for example Young's modulus, of the resulting bonding layer are matched to the corresponding properties of the substrate and/or the converter.

Suitable ceramic adhesives are produced, for example, from an inorganic, optionally powdery, solid and a liquid medium, optionally water. The inorganic solid may include, for example, MgO-, SiO2-, TiO2-, ZrO2- and/or Al2O3-based solids. An option is given to SiO2- and/or Al2O3-based solids,optionally Al2O3-based solids. The pulverulent solid may additionally include further pulverulent components which, for example, assist the setting of the ceramic adhesive. These may include, for example, boric acid, borates or alkali metal silicates, such as sodium silicates.

Ceramic adhesives may, for example, be made up directly before use from the pulverulent solid and water, and cure at room temperature.

The solid here optionally has a median grain size d50 of 1 to 100 μm, optionally 10 to 50 μm. The ceramic adhesive optionally has a coefficient of thermal expansion of 5-15×10⁻⁶ 1/K, optionally of 6 to 10×10⁶ 1/K. Suitable ceramic adhesives are produced, for example, from Resbond 920 or Resbond 940 HT (Polytec PT GmbH).

Bonding layers based on ceramic adhesives have, for example, a layer thickness of 50 to 500 μm, optionally of 100 to 350 μm, and optionally 150 to 300 μm.

In an advantageous embodiment, the binder is a metallic solder, optionally including an alloy of two or more metals. Suitable metallic solder alloys have a melting point lower than the melting point and/or the decomposition point of the individual constituents of the light conversion unit and/or higher than the maximum temperature of the light conversion element attained in operation at the solder. The melting point of the metallic solder alloy is optionally between 150° C. to 450° C., optionally between 180° C. to 320° C. and optionally between 200 to 300° C. Suitable metallic solder binders are, for example, silver solders and gold solders, optionally Ag/Sn, Ag/Au and Au/Sn solders, optionally Au/Sn solders, for example AuSn8020.

The binder may also take the form of a sintered sinter paste, optionally of an Ag-containing sinter paste.

The sintered sinter paste optionally has a layer thickness of 1 μm to 50 μm, optionally of 5 μm to 40 μm, optionally of 10 μm to 30 μm, especially optionally of 15 μm to 25 μm.

The sintered sinter paste optionally has a thermal conductivity of at least 50 W/mK, optionally at least 100 W/mK, optionally of at least 150 W/mK.

Especially in embodiments wherein the binder is a sintered sinter paste, it is advantageous that the surface of the light conversion element and the surface of the substrate that are bonded to one another have a coating. The light conversion element has optionally been provided with an Ag-containing thin layer, and optionally additionally with an Au-containing thin layer, or with a Cu-containing thin layer or an Ag-containing thick layer. Optional embodiments of the Ag-containing thin layer and of the Au-containing thin layer and of the Ag-containing thick layer are cited further up and are correspondingly applicable here. In advantageous embodiments, the surface of the substrate has a coating, where the coating is optionally an Au-containing coating and/or a NiP coating. The surface of the substrate has optionally been provided with a NiP layer, where the NiP layer optionally has a layer thickness of 1 μm to 10 μm, optionally 3 μm to 7 μm, and/or where the Au layer optionally has a layer thickness of 50 nm to 500 nm, optionally 100 nm to 400 nm, optionally 150 nm to 300 nm.

In embodiments in which the binder is a sintered sinter paste, the binding of the light conversion element and the substrate is effected according to the following steps:
a) providing a substrate and a light conversion element;
b) applying the sinter paste at least to a portion of the surface of the substrate and/or at least to a portion of the surface of the light conversion element;
c) contacting the surface of the substrate and the surface of the light conversion element, where at least a portion of the surface of the substrate and/or at least a portion of the surface of the light conversion element has been covered with the sinter paste;
d) sintering the composite obtained in step c).

In step a) of the method, a substrate and a light conversion element are provided. The surfaces of the substrate and/or of the light conversion element optionally have the coatings described in detail above.

In step b) a sinter paste is applied at least to part of the surface of the substrate and/or at least to part of the surface of the light conversion element. An option is given to applying a sinter paste at least to part of the substrate. The dosage of the amount of sinter paste is typically such that, after the sintering step d), the sintered sinter paste has a layer thickness of 1 μm to 50 μm, optionally of 5 μm to 40 μm, optionally of 10 μm to 30 μm, optionally of 15 μm to 25 μm.

In step c), the surface of the substrate and the surface of the light conversion element are contacted with one another, where at least part of the surface of the substrate and/or at least part of the surface of the light conversion element is covered with the sinter paste. Optionally, the surface of the light conversion element is contacted with a portion of the surface of the substrate, where the portion of the surface of the substrate has been at least partly covered with sinter paste. Advantageously, the contacting is effected with application of pressure, optionally at least 15 mN/mm², optionally more than 30 mN/mm², optionally more than 60 mN/mm².

In step d), the composite obtained in step c) is sintered. The sintering can be effected under an oxygen-containing atmosphere or under air or under a protective gas atmosphere, especially in an N₂ or Ar atmosphere. The sintering is effected at temperatures in the range from 180° C. to 300° C.

The sinter paste optionally has a sintering temperature of not more than 300° C., optionally not more than 280° C., optionally not more than 250° C. The sintering is optionally effected by heating the composite to the desired sintering temperature, advantageously by heating in a first step up to a first temperature, at optionally at least 0.5 K/min, optionally at least 0.75 K/min, and/or at not more than 3 K/min, optionally not more than 2 K/min. Optionally, the first temperature is in the range from 70° C. to 120° C., optionally 80° C. to 105° C. Optionally, after attainment of the first temperature, the temperature is maintained for 1 min to 60 min, optionally for 5 min to 45 min, optionally 20 min to 40 min. Optionally, in a second step, the composite is subsequently heated up to a second temperature at optionally at least 1.0 K/min, optionally at least 1.5 K/min, and/or not more than 3.5 K/min, optionally not more than 3 K/min. The second temperature is optionally within a range from 180° C. to 300° C., optionally 200° C. to 280° C., and corresponds to the sintering temperature. Optionally, after the second temperature, i.e. the sintering temperature, has been attained, the temperature is maintained for at least 10 min, optionally at least 20 min or at least 30 min, and/or for not longer than 60 min, optionally not longer than 50 min or 40 min. This is followed by cooling of the composite, optionally to room temperature.

In embodiments in which the light conversion element has been bonded to a mirror on the rear side, optionally to an Ag minor or to a silver-coated substrate, where the minor is optionally formed by the substrate or has been applied to the substrate, it may be the case that binders are present between the minor or the reflective substrate and the light conversion element, optionally including or composed of an optically transparent organic or inorganic adhesive and/or composed of a transparent material having a lower refractive index than the refractive index of the light conversion element, optionally an optically transparent organic adhesive having a lower refractive index than the refractive index of the light conversion element, where the binder optionally has a thickness in the region of not more than 30 μm, optionally in the range from 10 to 20 μm.

It may be the case that the surface of the light conversion element facing the incident light has been partly or fully provided with a single- or multilayer antireflection coating.

In an optional embodiment of the present invention, the light conversion element has a porosity of at least 0.5%, optionally of at least 1.5%, optionally of at least 3%, optionally between 3% and 7%, especially based on the volume of the pores in relation to the total volume of the light conversion element.

Alternatively or additionally, the light conversion element may have, in a cross section, at least 200 pores per square millimeter, optionally at least 300 pores per square millimeter, optionally at least 400 pores per square millimeter.

A cross section of the light conversion element may especially be examined by scanning electron microscopy (SEM). Such a cross section through the light conversion element may also be polished. In the polished cross section (polished section), the polished pores in particular may then be visible, where these may in turn be detectable by way of SEM in particular. It is possible, for example, to consider and evaluate an area of 61,800 μm² in a cross section.

Especially in a cross section, for example over such an area of 61,800 μm² of the cross section, at least 20,000 pores per cm², optionally at least 30,000 pores per cm², optionally at least 40,000 pores per cm², may be present. Alternatively or additionally, 20,000 to 200,000 pores per cm², optionally 30,000 to 150,000 pores per cm², optionally 40,000 to 120,000 pores per cm², may be present in a cross section.

The median diameter of the pores, especially of the pores present in a cross section, may be between 100 nm and 3000 nm, optionally between 300 nm and 1500 nm, optionally between 400 nm and 1200 nm.

The median divides a dataset, i.e. a sample or a distribution, in the present case, for example, the diameter of the pores present in cross section or the diameter of the crystallites, into two equal portions, such that the values, i.e. the pore diameters, in one half are not greater than the median value, and in the other half are not less.

The first phase of the light conversion element may include a multitude of crystallites, where the median diameter of these crystallites is optionally between 300 nm and 5000 nm, optionally between 500 nm and 3000 nm.

The second phase of the light conversion element may include a multitude of crystallites, where the median diameter of these crystallites is optionally between 300 nm and 5000 nm, optionally between 500 nm and 3000 nm.

It may be the case that the ratio of the median diameter of the pores, especially of the pores present in a cross section, and the median diameter of the crystallites in the first and/or second phase, especially of the crystallites of the first and/or second phase that are present in the cross section, is between 0.02 and 10, optionally between 0.06 and 5, optionally between 0.13 and 2.4.

It may further be the case that optionally at least 1%, optionally at least 5% of the pores, especially of the pores present in a cross section, are included in the first phase, such that these pores solely adjoin material of the first phase.

Optionally at least 1%,optionally at least 5% of the pores, especially of the pores present in a cross section, may be included in the second phase, such that these pores solely adjoin material of the second phase.

It is optionally possible for at least 1%, optionally at least 5%, of the pores, especially of the pores present in a cross section, to be disposed between the first phase and the second phase such that these pores adjoin both material of the first phase and material of the second phase.

The percentages specified are each based in particular on the number of specific pores detected in the cross section in relation to the total number of pores detected in the cross section.

The pores have optionally formed during the sintering process, optionally without using any pore formers, and have especially not been introduced subsequently, for example by selective etching.

The porosity, especially in a cross section, the number of pores per square millimeter, especially in a cross section, and/or the median diameter of the pores, especially in a cross section, in the light conversion element is optionally homogeneous and/or, on a surface of the light conversion element, is equal to or not more than 10% different from a cross section through the interior of the light conversion element.

The first phase of the light conversion element may have a refractive index at 500 nm of not less than 1.8, especially between 1.8 and 1.9.

The second phase of the light conversion element may have a refractive index at 500 nm of not more than 1.8, especially between 1.7 and 1.8.

The refractive index of the first phase of the light conversion element at 500 nm is optionally not less than the refractive index of the second phase of the light conversion element at 500 nm. There is optionally a difference between the refractive index of the first phase and of the second phase of the light conversion element at 500 nm by not more than 0.15, optionally not more than 0.1, optionally not more than 0.7 and optionally not more than 0.5.

The refractive indices of the first and second phases of the light conversion element may be ascertained, for example, on double-sidedly polished samples of known thickness of the respective material by way of ellipsometry. In one embodiment of the present invention, the coefficient of scatter of the light conversion element for a wavelength of 600 nm is greater than 150 cm⁻¹, optionally greater than 300 cm⁻¹, and is optionally between 300 cm⁻¹ and 1200 cm⁻¹.

The coefficient of scatter is ascertained by fitting a model described in V. Hagemann, A. Seidl, G. Weidmann: Static ceramic phosphor assemblies for high power high luminance SSL-light sources for digital projection and specialty lighting, Proc. of SPIE Vol. 11302 113021N-11, SPIE OPTO, San Francisco 2020, to the backscatter actually measured at 600 nm.

In one embodiment of the present invention, the first phase can be described by the composition (A_{1-y}R_{y})₃B₅O₁₂ where A includes one or more elements from the group of lanthanoids and Y, R includes one or more elements from the group of lanthanoids, B includes one or more elements from the group of Al, Ga, In, where y describes the proportion of atoms of R at the A site of the crystal lattice, and 0<y<0.02, optionally 0<y<0.012, optionally 0.001<y<0.009.

In the aforementioned embodiment, A may be selected from one or more of the elements Y, Gd, Lu, and/or B from one or more of the elements Al, Ga, In.

In one embodiment of the present invention, the second phase of the light conversion element includes or consists of aluminium oxide.

For the proportion by volume z of the second phase, it may be the case that: 0.05<z<0.95, optionally 0.3<z<0.7, optionally 0.45<z<0.7.

In one embodiment, the light conversion element includes one or more of the systems [(Y_{1-y}Ce_{y})₃Al₅O₁₂]_{1-z}[Al₂O₃]_{z}, [(Lu_{1-y}Ce_{y})₃Al₅O₁₂]_{1-z}[Al₂O₃]_{z}, [(Y_{1-x-y}GdₓCe_{y})₃Al₅O₁₂]_{1-z}[Al₂O₃]_{z}, [(Lu_{1-y}Ce_{y})₃(Al_{1-w}Ga_{w})₃O₁₂]_{1-z}[Al₂O₃]_{z}, especially when 0<x<0.2 and 0<w<0.3.

It may be the case that the thermal conductivity of the light conversion element at room temperature is greater than 10 W/mK, optionally greater than 12 W/mK, optionally greater than 14 W/mK.

The present invention further relates to a light conversion unit formed by or including a light conversion element having a front side and a rear side, wherein the light conversion element is set up to be illuminated by primary light on its front side and to emit secondary light with an altered wavelength compared to the primary light on its front side.

The light conversion unit optionally includes a substrate which is connected directly or indirectly to the rear side of the light conversion element and is optionally in the form of a heatsink, and optionally a binder which is between the light conversion element and the substrate and is optionally in the form of an organic adhesive, glass, ceramic adhesive, inorganic adhesive, sintered sinter paste and/or metallic solder alloy, optionally of a metallic solder alloy or sintered sinter paste, optionally of a metallic solder alloy.

The light conversion element includes a first phase including a light-converting ceramic material and a second phase including a further ceramic material, wherein the second phase has higher thermal conductivity than the first phase.

The light conversion element includes a multitude of pores, which especially serve to scatter light.

The above-described illumination device or light conversion unit may find use, for example, in “dynamic” applications (color wheels) or “static” applications (dies on heatsink).

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 shows experimentally ascertained reflection spectra of converter ceramics with and without addition of Al2O3, at different porosity;

FIG. 2 shows coefficient of scatter of converter ceramics calculated from the measured reflectivity, with and without addition of Al₂O₃, at different porosity;

FIG. 3 shows SEM image of a mixed ceramic of composition [(Y_{0.993}Ce_{0.007})₃Al₅O₁₂]_{0.46}[Al₂O₃]_{0.54}, light phase: YAG, dark phase: Al₂O₃ and pores;

FIG. 4 shows thermal conductivity at 20° C. of the materials from Table 2 (for porosities in this order of magnitude, thermal conductivity decreases in a linear manner with rising porosity; the mixed ceramic shows much higher thermal conductivity than the single-phase YAG ceramic);

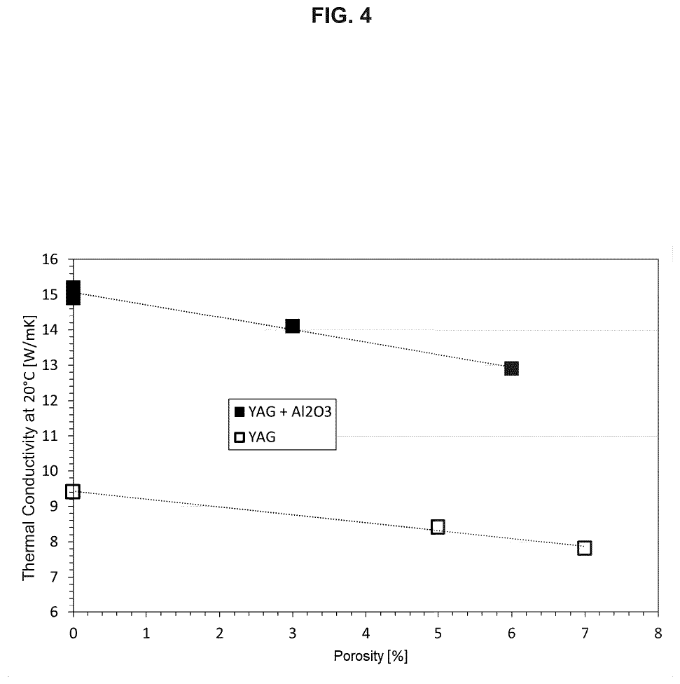

FIG. 5 shows SEM image of a mixed ceramic of composition [(Y_{0.989}Ce_{0.011})₃Al₅O₁₂]_{0.65}[Al₂O₃]_{0.35}, light phase: (Y_{0.989}Ce_{0.011})₃Al₅O₁₂, dark phase: Al₂O₃, some visible pores (very dark) are marked by way of example;

FIG. 6 shows SEM image of a mixed ceramic of composition [(Lu_{0.9937}Ce_{0.008})₃Al₅O₁₂]_{0.5}[Al₂O₃]_{0.5};

FIG. 7 shows SEM image of a mixed ceramic of composition [(Lu_{0.9937}Ce_{0.008})₃Al₅O₁₂]_{0.5}[Al₂O₃]_{0.5}, indicating visible pores present (very dark), light phase: (Lu_{0.9937}Ce_{0.008})₃Al₅O₁₂, dark phase: Al₂O₃;

FIG. 8 shows coefficient of scatter calculated from the measured reflectivity for the converter ceramics from Table 3;

FIG. 9 shows distributions of pore diameter in a cross section (polished section), where the diameters are given in nm.

Corresponding reference characters indicate corresponding parts throughout the several views. The exemplifications set out herein illustrate at least one embodiments of the invention, and such exemplifications are not to be construed as limiting the scope of the invention in any manner.

### DETAILED DESCRIPTION OF THE INVENTION

For efficient reflective lighting devices, especially SSL (solid state lighting), with a light conversion element including a mixed ceramic, pores enable sufficiently large scatter (sufficiently large coefficient of scatter). This is especially true of the materials Al₂O₃ and YAG.

The refractive indices of the materials Al₂O₃ and YAG do not differ significantly from one another: the refractive index of Al₂O₃ is about 1.77, that of YAG about 1.83. The optical scatter effect resulting from a mixed ceramic alone can therefore be estimated as being comparatively small without pores.

This state of affairs was also demonstrated experimentally by in-house studies. Converter ceramics of different porosity (i.e. with different scatter properties) were produced from Ce:LuAG, in some cases without and in some cases with addition of aluminium oxide. The theoretical densities r₁ (here: of Lu₃Al₅O₁₂) and r₂ (here: of Al₂O₃) and the masses m₁ and m₂ are used to find the theoretical density rₜₕ of the mixed ceramic:

$${ρ}_{th} = \frac{{m}_{1} + {m}_{2}}{\frac{{m}_{1}}{{ρ}_{1}} + \frac{{m}_{2}}{{ρ}_{2}}}$$

The sintered bodies produced were measured with regard to their density r, giving a porosity P in the sintered body:

$$P = 1 - \frac{ρ}{{ρ}_{th}}$$

The sintered bodies of different porosity were used to prepare (double-sidedly polished) samples of a particular thickness in the range between 100 and 250 μm. Reflectivity was measured in the green-red spectral region (since absorption here is negligibly small). The reflectivity thus ascertained includes both Fresnel reflexion and backscatter.

A model was employed which is elucidated in: V. Hagemann, A. Seidl, G. Weidmann: Static ceramic phosphor assemblies for high power high luminance SSL-light sources for digital projection and specialty lighting. Proc. of SPIE Vol. 11302 113021N-11, SPIE OPTO, San Francisco 2020.

By way of the model specified, it is possible to simulate these experimental conditions. Since absorption in this spectral region is negligible, the intensity reflected depends on the refractive index of the double-sidedly polished platelet, on the thickness thereof, and on the coefficient of scatter. Since the refractive index (or, as the case may be, the average refractive index) and the thickness are known, it is possible to use such measurements to calculate the coefficient of scatter.

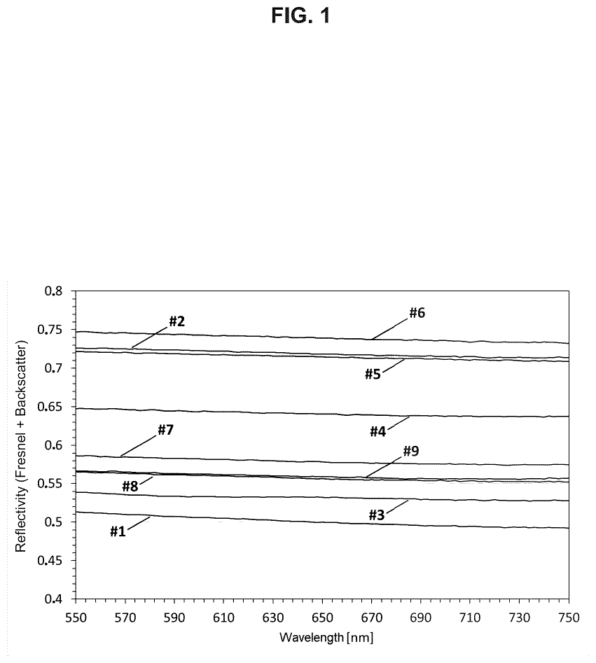

FIG. 1 shows the reflection spectra of the 9 illustrative samples thus analyzed.

Table 1 summarizes the results of measurement and simulation.

TABLE 1
Experimentally ascertained reflectivities and coefficients of scatter
calculated therefrom for converter ceramics with
and without addition of Al₂O₃, at different porosity:

| Sample | #1 | #2 | #3 | #4 | #5 | #6 | #7 | #8 | #9 |
|---|---|---|---|---|---|---|---|---|---|
| Composition | LuAG | LuAG | LuAG- | LuAG- | LuAG- | LuAG- | LuAG | LuAG | LuAG- |
| | | | Al₂O₃ | Al₂O₃ | Al₂O₃ | Al₂O₃ | | | Al₂O₃ |
| Proportion by | — | — | 5 | 50 | 50 | 50 | — | — | 50 |
| volume of Al₂O₃ | | | | | | | | | |
| [vol %] | | | | | | | | | |
| Porosity [%] | 0.9 | 4.2 | 0.9 | 2.3 | 4.7 | 5.3 | 3.2 | 4.3 | 4.1 |
| Sample thickness | 215 | 240 | 235 | 235 | 250 | 250 | 215 | 100 | 100 |
| [μm] | | | | | | | | | |
| Refractive index | 1.82 | 1.82 | 1.82 | 1.79 | 1.79 | 1.79 | 1.82 | 1.82 | 1.79 |
| R (at 600 nm) | 0.506 | 0.723 | 0.533 | 0.644 | 0.718 | 0.743 | 0.582 | 0.561 | 0.562 |
| Calculated | 123 | 438 | 131 | 262 | 400 | 471 | 197 | 366 | 357 |
| coefficient of | | | | | | | | | |
| scatter [1/cm] | | | | | | | | | |

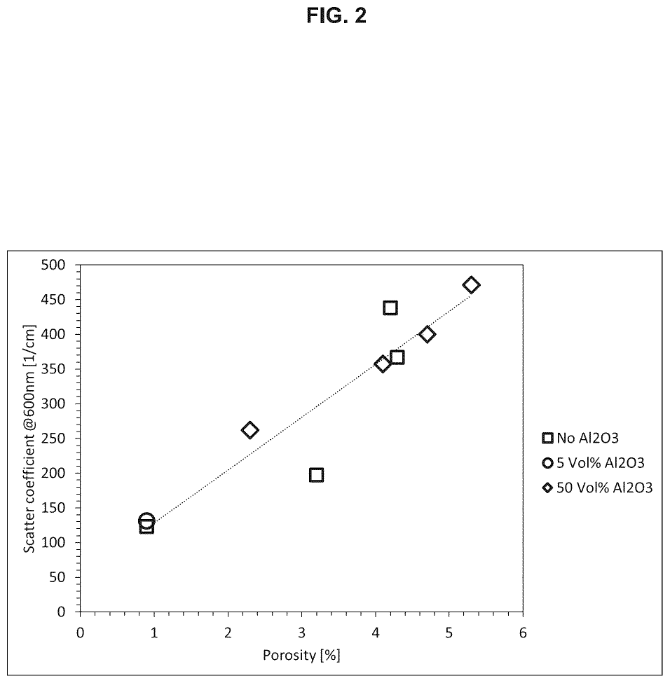

FIG. 2 shows firstly that, in the materials analyzed, the coefficient of scatter rises roughly proportionally relative to porosity, which is indeed to be expected (the coefficient of scatter is always proportional to the number of scatter sites). In particular, however, it can be seen that the material even with a very high proportion of Al₂O₃ does not have significantly more scatter than the material without Al₂O₃.

In a reflectance geometry where the light hits the front side of the light conversion element and the secondary light is also released from that front side, depending on the application, optional coefficients of scatter are between about 150 and about 1200 cm−1. In order to achieve such coefficients of scatter, irrespective of the presence of Al₂O₃ in the material, porosities of at least 1% are optionally provided.

A reflective lighting device especially has a mixed ceramic including pores. In other words, the mixed ceramic may be produced as a porous mixed ceramic. In this way, it is advantageously possible to adjust the coefficient of scatter within a range between 150 cm⁻¹ and 1200 cm⁻¹. Optionally, the second of the light conversion elements may include Al₂O₃.

Porous mixed ceramics of this kind can be produced in different ways.

One way is to mix powders of the pure oxides yttrium oxide, lutetium oxide, aluminium oxide, gallium oxide, gadolinium oxide and cerium oxide according to the desired composition and stoichiometry. The “superstoichiometrically” added aluminium oxide results in the Al₂O₃ phase in the matrix, and the balance in the respectively desired garnet phase. After addition of ethanol (or water or another fluid), dispersing aids and compressing aids, grinding balls are added to the slip, which is finely ground in a drum by way of a roller bench. The slip is subsequently dried and then compressed to green bodies. The green bodies are debindered at more than about 500° C., followed by reactive sintering under air, oxygen or else under reduced pressure at sufficiently high temperature of more than about 1400° C. until attainment of the desired density or porosity. If the porosity should still be too high, there may be one or more further sintering operations thereafter until the target value has been attained.

Another way is to mix powder of presynthesized garnet of a desired composition with Al₂O₃ powder. If the garnet powder still does not contain Ce, cerium oxide powder may also be added in the desired amount. After addition of ethanol (or water or another fluid), dispersing aids and compressing aids, grinding balls are added to the slip, which is finely ground in a drum by way of a roller bench. The slip is subsequently dried and then compressed to green bodies. The green bodies are debindered at more than about 500° C., followed by reactive sintering under air, oxygen or else under reduced pressure at sufficiently high temperature of more than 1400° C. until attainment of the desired density or porosity. If the porosity should still be too high, there may be one or more further sintering operations thereafter until the target value has been attained.

This can be effected for any composition according to the description [(A_{1-y}R_{y})₃B₅O₁₂]_{1-z}[Al₂O₃]_{z} where A includes one or more elements from the group of lanthanoids and Y, R includes one or more elements from the group of lanthanoids, B includes one or more elements from the group of Al, Ga, In, where y describes the proportion of atoms of R at the A site of the crystal lattice, and z the proportion by volume of Al₂O₃ in the solid state of the ceramic matrix (i.e. neglecting pores), with 0<y<0.02 and 0.05<z<0.95.

A is optionally selected from one or more of the elements Y, Gd, Lu, and B from one or more of the elements Al, Ga, and 0<y<0.012 and 0.3<z<0.7.

Optionally, 0.001<y<0.009 and 0.45<z<0.7 for the systems [(Y_{1-y}Ce_{y})₃Al₅O₁₂]_{1-z}[Al₂O₃]_{z}, [(Lu_{1-y}Ce_{y})₃ Al₅O₁₂]_{1-z}[Al₂O₃]_{z}, [(Y_{1-x-y}GdₓCe_{y})₃Al₅O₁₂]_{1-z}[Al₂O₃]_{z}, [(Lu_{1-y}Ce_{y})₃(Al_{1-w}Ga_{w})₃O₁₂]_{1-z}[Al₂O₃]_{z} when 0<x<0.2 and 0<w<0.3.

Especially for the synthesis route from the pure oxides, it is possible that not all oxide of component R is incorporated into the garnet lattice, but remains in the ceramic matrix (with a very small proportion by volume) as a second oxide alongside the aluminium oxide. The higher the proportion by volume z of Al₂O₃, the higher the probability that not all R will get into the garnet. Although the solubility of the lanthanides in Al₂O₃ is negligibly low, it is possible that traces of component R remain in the volume region of the second phase, for example Al₂O₃, and are not incorporated into phase 1, for example YAG. This may need to be taken into account in calculating the oxides to be weighed out. For example, it is necessary to weigh out somewhat more CeO₂ than the calculation suggests assuming full incorporation, in order to obtain the desired proportion y in the garnet lattice in the ceramic.

The ceramic bodies thus produced are processed further to give components for lighting devices, for example SSL components.

### Example 1

292.0 g of Y₂O₃, 715.0 g of Al₂O₃ and 3.0 g of CeO₂ were mixed in the manner described above and sintered to give ceramic bodies of different porosity. This ratio of amounts corresponds theoretically, assuming full incorporation of the Ce, to the composition [(Y_{0.993}Ce_{0.007})₃Al₅O₁₂]_{0.46}[Al₂O₃]_{0.54}.

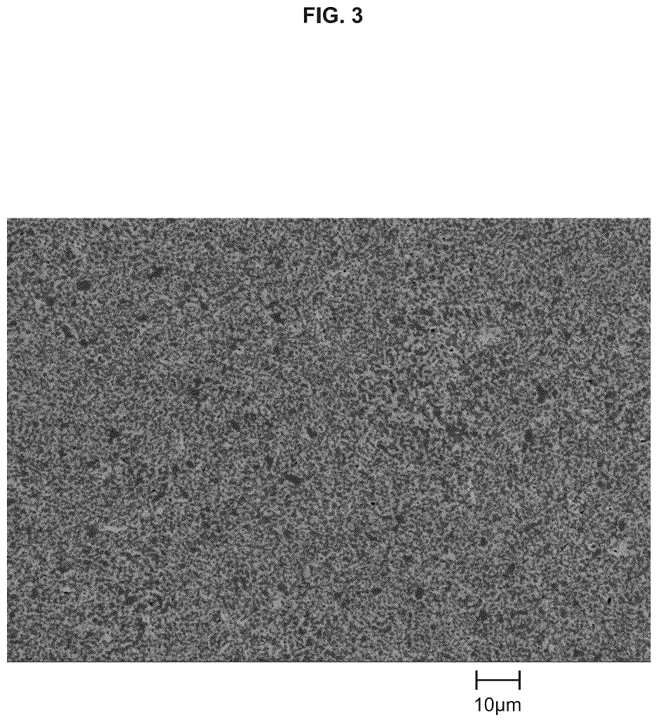

FIG. 3 shows the matrix of the ceramic thus obtained (here by way of example specimen 1-4 with a measured porosity of 2%).

Table 2 lists the variants produced and the thermal conductivities measured thereon, together with references that have been produced without addition of Al₂O₃. The addition of Al₂O₃ increases thermal conductivity by about 60%. This is also shown in FIG. 3.

TABLE 2
Specimens of different porosities of the [(Y_{0.993}Ce_{0.007})₃ Al₅O₁₂]_{0.46}[Al₂O₃]_{0.54} type, and thermal
conductivity thereof; for comparison, some measurement data for references without added
aluminium oxide:

| | | Proportion by | | | Thermal |
|---|---|---|---|---|---|
| Sample | Material | volume of | Ce content y | Porosity P | conductivity 1 |
| No. | type | Al₂O₃ z | in the YAG * | [%] | [W/mK] at 20° C. |
| 1-1 | YAG + Al₂O₃ | 0.54 | 0.007 | 0 | 15.2 |
| 1-2 | YAG + Al₂O₃ | 0.54 | 0.007 | 0 | 14.9 |
| 1-3 | YAG + Al₂O₃ | 0.54 | 0.007 | 6 | 12.9 |
| 1-4 | YAG + Al₂O₃ | 0.54 | 0.007 | 3 | 14.1 |
| Ref1 | YAG | 0 | 0.0035 | 0 | 9.4 |
| Ref2 | YAG | 0 | 0.0035 | 5 | 8.4 |
| Ref3 | YAG | 0 | 0.0035 | 7 | 7.8 |

* Assumption: all Ce is in the YAG

### Example 2

716.8 g of Y₂O₃, 1270.4 g of Al₂O₃ and 12.8 g of CeO₂ were mixed in the manner described above and sintered to give ceramic bodies of different porosity. This ratio of amounts corresponds theoretically, assuming full incorporation of the Ce, to the composition [(Y_{0.989}Ce_{0.011})₃Al₅O₁₂]_{0.65}[Al₂O₃]_{0.35}.

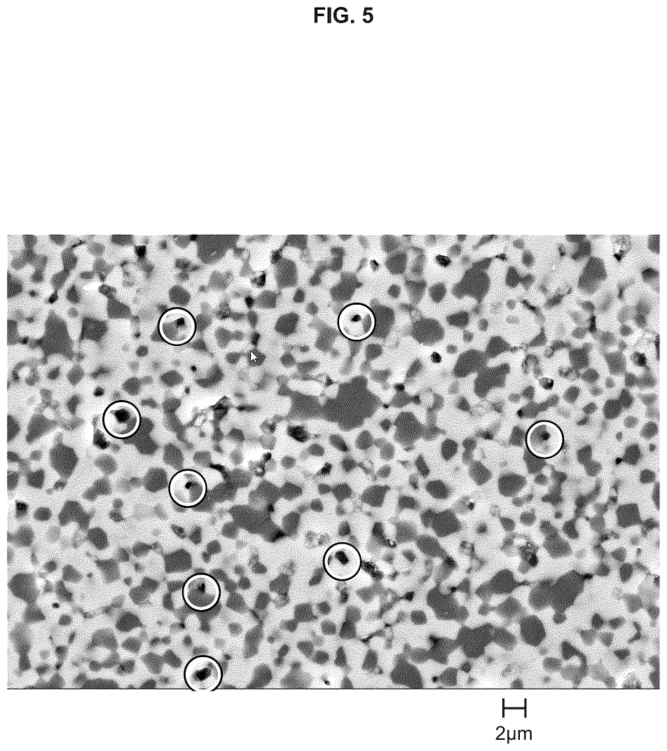

FIG. 5 shows the matrix of the ceramic thus obtained (here by way of example specimen 2.3 with a measured porosity of 7%). Some visible pores are marked by circles.

### Example 3

482.9 g of Lu₂O₃, 617.1 g of Al₂O₃ and 3.3 g of CeO₂ were mixed in the manner described above and sintered to give ceramic bodies of different porosity. This ratio of amounts corresponds theoretically, assuming full incorporation of the Ce, to the composition [(Lu_{0.992}Ce_{0.008})₃Al₅O₁₂]_{0.5}[Al₂O₃]_{0.5}.

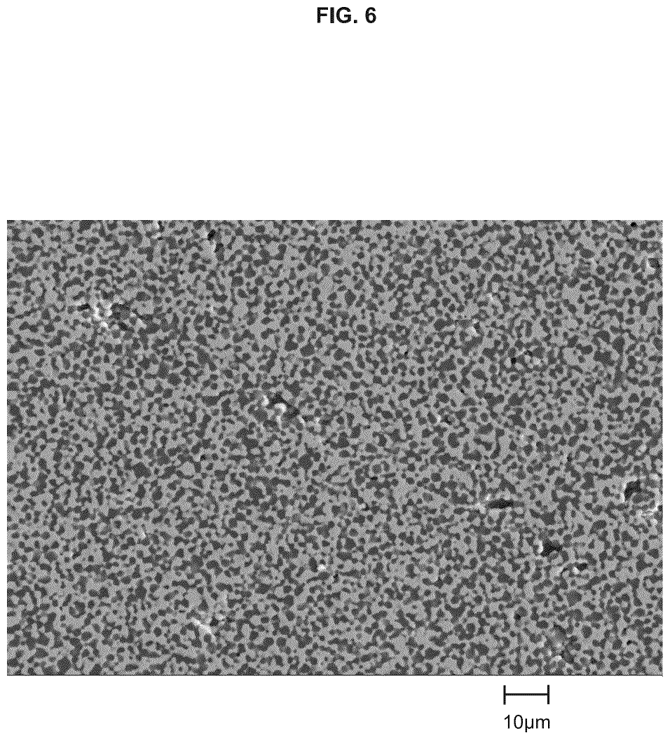

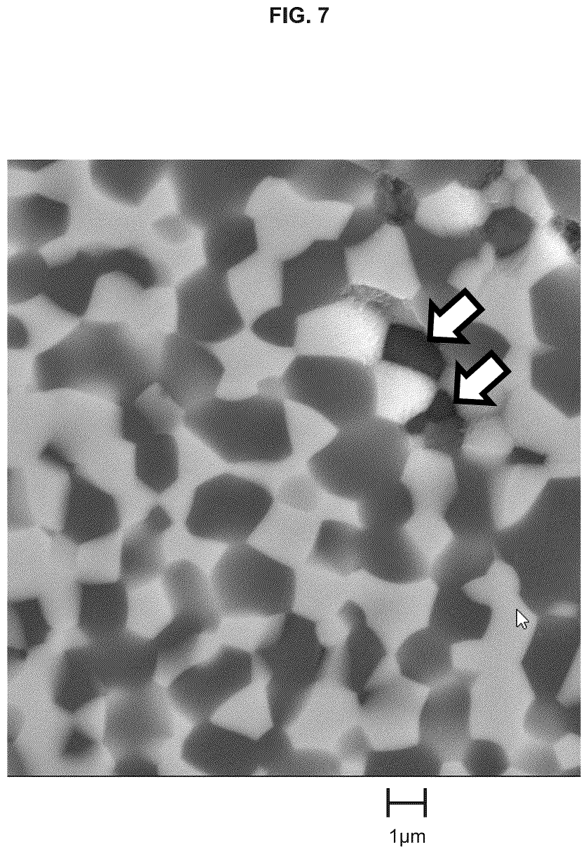

FIGS. 6 and 7 show the matrix of the ceramic thus obtained (here by way of example specimen 3.4 with a measured porosity of 4%).

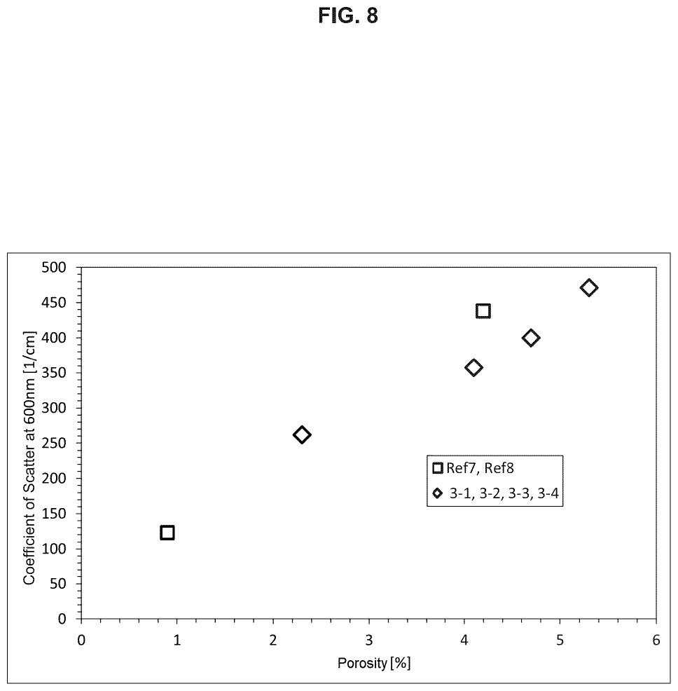

FIG. 8 and Table 3 show the variants produced and the coefficients of scatter measured thereon (in this regard see also the section “Objective”), together with references that have been produced without addition of Al₂O₃. The addition of Al₂O₃ has no significant effect on the coefficient of scatter in the case of porous ceramic.

TABLE 3
Specimens of different porosities of the [(Lu_{0.9937}Ce_{0.008})₃ Al₅O₁₂]_{0.5}[Al₂O₃]_{0.5} type, and
coefficients of scatter thereof; for comparison, some measurement data for references
without added aluminium oxide:

| | | Proportion by | | | Coefficient of |
|---|---|---|---|---|---|
| Sample | Material | volume of | Ce content y | Porosity P | scatter s [cm⁻¹] |
| No. | type | Al₂O₃ z | in the LuAG * | [%] | at 600 nm |
| 1-1 | LuAG + Al₂O₃ | 0.5 | 0.008 | 2.3 | 262 |
| 1-2 | LuAG + Al₂O₃ | 0.5 | 0.008 | 4.1 | 357 |
| 1-3 | LuAG + Al₂O₃ | 0.5 | 0.008 | 4.7 | 400 |
| 1-4 | LuAG + Al₂O₃ | 0.5 | 0.008 | 5.3 | 471 |
| Ref1 | LuAG | 0 | 0.005 | 0.9 | 123 |
| Ref2 | LuAG | 0 | 0.005 | 4.2 | 438 |

* Assumption: all Ce is in the YAG

### Example 4

SEM images of cross sections (polished sections) of a light conversion element were created. Magnification was set to 2000, and in each case 4×105 μm*150 μm images were created. This corresponds to 0.01575 mm² per image.

The pore areas were determined by image analysis, and this was used to undertake an evaluation of the pore distribution. For this purpose, each pore was assigned a diameter corresponding to a round pore area.

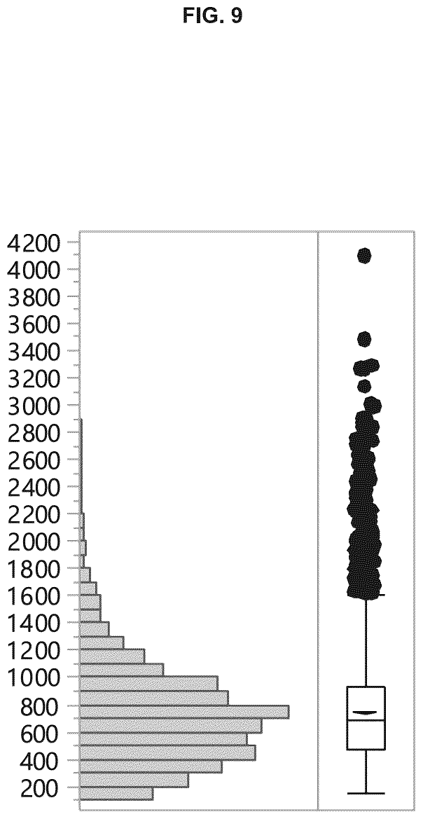

FIG. 9 shows the distribution of the pore diameters in nm. Supplementary data are tabulated below:

| Quantiles | | | Statistical indices | |
|---|---|---|---|---|
| 100.0% | Maximum | 4083.7350008 | Mean | 739.98676 |
| 99.5% | | 2555.9718512 | Standard deviation | 413.46262 |
| 97.5% | | 1736.5651344 | Standard error of mean | 5.7074135 |
| 90.0% | | 1224.1743929 | Upper 95% CI of mean | 751.17567 |
| 75.0% | Quartile | 927.05808486 | Lower 95% CI of mean | 728.79785 |
| 50.0% | Median | 683.57802255 | N | 5248 |
| 25.0% | Quartile | 470.68426868 | | |
| 10.0% | | 271.74968923 | | |
| 2.5% | | 155.5363345 | | |
| 0.5% | | 155.5363345 | | |
| 0.0% | Minimum | 155.5363345 | | |

Considering the medians of such distributions, depending on the process regime and the particle size distribution of the starting powder used, an optional median of the pore diameters between 100 nm and 3000 nm, optionally between 300 nm and 1500 nm, optionally between 400 nm and 1200 nm, is found. The grain sizes of YAG, LuAG and Al₂O₃ are in a similar order of magnitude, but with broader distribution and sometimes slightly higher median values.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A lighting device, comprising:
a light source configured for emitting a primary light;
a light conversion unit formed by or comprising:
a light conversion element including a front side and a rear side,
wherein the light conversion element is configured for being illuminated by the primary light on the front side and for emitting a secondary light with an altered wavelength compared to the primary light on the front side,
wherein the light conversion element includes a first phase including a light-converting ceramic material and a second phase including a further ceramic material, the second phase having a higher thermal conductivity than the first phase, and
wherein the light conversion element includes a plurality of pores.

2. The lighting device according to claim 1, wherein at least one of:
the light conversion element has a porosity of at least 0.5%; and
the light conversion element in a cross-section has at least 200 ones of the plurality of pores per square millimeter.

3. The lighting device according to claim 1, wherein at least one of:
a median diameter of the plurality of pores is between 100 nm and 3000 nm;
the first phase includes a plurality of crystallites; and
the second phase includes a plurality of crystallites.

4. The lighting device according to claim 3, wherein a ratio of the median diameter of the plurality pores and a median diameter of the crystallites of at least one of the first phase and the second phase is between 0.02 and 10.

5. The lighting device according to claim 1, wherein at least one of:
at least 1% of the plurality of pores are included in the first phase such that the at least 1% of the plurality of pores that are included in the first phase solely adjoin a material of the first phase;
at least 1% of the plurality of pores are included in the second phase such that the at least 1% of the plurality of pores that are included in the second phase solely adjoin a material of the second phase; and
at least 1% of the plurality of pores are disposed between the first phase and the second phase such that the at least 1% of the plurality of pores that are disposed between the first phase and the second phase adjoin both a material of the first phase and a material of the second phase.

6. The lighting device according to claim 1, wherein at least one of:
(a) the plurality of pores have formed during a sintering process; and
(b) at least one of a porosity, a number of the plurality of pores per square millimeter, and a median diameter of the plurality of pores in the light conversion element is at least one of homogeneous and, on a surface of the light conversion element, is equal to or not more than 10% different from a cross-section through an interior of the light conversion element.

7. The lighting device according to claim 1, wherein at least one of:
(a) the first phase has a refractive index at 500 nm of not less than 1.8; and
(b) the second phase has a refractive index at 500 nm of not more than 1.8.

8. The lighting device according to claim 1, wherein a refractive index of the first phase of the light conversion element at 500 nm is not less than a refractive index of the second phase of the light conversion element at 500 nm.

9. The lighting device according to claim 1, wherein a coefficient of scatter of the light conversion element for a wavelength of 600 nm is greater than 150 cm⁻¹.

10. The lighting device according to claim 1, wherein the first phase includes a composition (A_{1-y}R_{y})₃B₅O₁₂, where A comprises at least one element from a group of lanthanoids and Y, R comprises at least one element from a group of lanthanoids, B comprises at least one element from a group of Al, Ga, and In, where y is a proportion of atoms of R at an A site of a crystal lattice, and 0<y<0.02.

11. The lighting device according to claim 10, wherein A is selected from at least one of elements Y, Gd, and Lu, and B is selected from at least one of elements Al, Ga, and In.

12. The lighting device according to claim 1, wherein the second phase comprises or consists of aluminium oxide.

13. The lighting device according to claim 1, wherein, for a proportion by volume z of the second phase, 0.05<z<0.95.

14. The lighting device according to claim 1, further comprising at least one of the following systems: [(Y_{1-y}Ce_{y})₃Al₅O₁₂]_{1-z}[Al₂O₃]_{z}, [(Lu_{1-y}Ce_{y})₃Al₅O₁₂]_{1-z}[Al₂O₃]_{z}, [(Y_{1-x-y}GdₓCe_{y})₃Al₅O₁₂]_{1-z}[Al₂O₃]_{z}, [(Lu_{1-y}Ce_{y})₃(Al_{1-w}Ga_{w})₃O₁₂]_{z-z}[Al₂O₃]_{z} when 0<x<0.2 and 0<w<0.3.

15. The lighting device according to claim 1, wherein the thermal conductivity of the light conversion element at room temperature is greater than 10 W/mK.

16. The lighting device according to claim 1, wherein the light conversion unit further includes a substrate which is connected directly or indirectly to the rear side of the light conversion element.

17. The lighting device according to claim 16, wherein the substrate is a heatsink.

18. The lighting device according to claim 16, wherein the light conversion unit further includes a binder positioned between the light conversion element and the substrate.

19. The lighting device according to claim 1, wherein the light source is formed as a laser or a light-emitting diode.

20. A light conversion unit, comprising:
a light conversion element including a front side and a rear side,
wherein the light conversion element is configured for being illuminated by a primary light on the front side and for emitting a secondary light with an altered wavelength compared to the primary light on the front side,
wherein the light conversion element includes a first phase including a light-converting ceramic material and a second phase including a further ceramic material, the second phase having a higher thermal conductivity than the first phase, and
wherein the light conversion element includes a plurality of pores.
